(19) United States
(12) Patent Application Publication
(10) Pub. No.: US 2013/0307167 A1
(43) Pub. Date: Nov. 21, 2013

(54) PHENOLIC OLIGOMER AND METHOD FOR PRODUCING THE SAME

(71) Applicants: Kiyoshi Oomori, Yamaguchi (JP); Yasunori Fukuda, Yamaguchi (JP); Yoshikazu Nakagawa, Yamaguchi (JP); Yoshitaka Ooue, Yamaguchi (JP); Noriyuki Mitani, Yamaguchi (JP)

(72) Inventors: Kiyoshi Oomori, Yamaguchi (JP); Yasunori Fukuda, Yamaguchi (JP); Yoshikazu Nakagawa, Yamaguchi (JP); Yoshitaka Ooue, Yamaguchi (JP); Noriyuki Mitani, Yamaguchi (JP)

(73) Assignee: MEIWA PLASTIC INDUSTRIES, LTD., Yamaguchi (JP)

(21) Appl. No.: 13/882,052

(22) PCT Filed: Oct. 26, 2011
(86) PCT No.: PCT/JP2011/074719

§ 371 Date: Jul. 11, 2013

(30) Foreign Application Priority Data
Oct. 26, 2010 (JP) 2010-239839

(51) Int. Cl. C08G 8/22; H01L 23/29

(52) U.S. Cl. CPC C08G 8/22; H01L 23/295
USPC 257/789; 568/720; 528/98; 525/523

(57) ABSTRACT

The present invention relates to techniques including a phenolic oligomer of general formula (1):

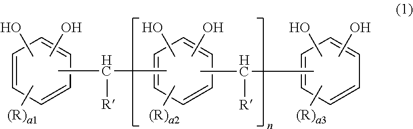

wherein n is an integer of 0 to 15, Rs are allyl groups, a1 and a3 are each independently 0, 1, 2 or 3, each a2 is independently 0, 1 or 2, each R′ is independently a hydrogen atom, an alkyl group having 1 to 10 carbon atoms or an aryl group, and proviso that at least one of a1, each a2 and a3 represents 2, and a method for producing such phenolic oligomer.

### TECHNICAL FIELD

The present invention relates to phenolic oligomers that are used as curing agents for epoxy resins in various materials such as binders, compounds, coating materials, laminating materials and molding materials, as well as can be used as materials for epoxy novolac resins and are in particular best suited as curing agents for epoxy resins used in semiconductor sealing materials and underfill materials. The present invention also relates to methods for producing such phenolic oligomers, and to other associated techniques.

### BACKGROUND ART

Conventionally, electronic components, in particular, semiconductors are dominantly sealed with resins due to reasons such as productivity and costs. At present, epoxy resin compositions are most frequently used which exhibit excellent properties such as workability, moldability, electrical properties, moisture resistance and mechanical properties. Recently, demands have been placed on electric and electronic devices to be reduced in weight, thickness and size as well as to be multifunctional. This has led to a marked increase in the degree of integration of semiconductors. Consequently, the mainstream technique for mounting semiconductor packages to printed circuit boards (PCB) has shifted from conventional dual inline package (DIP) mounting to surface mounting (BGA, SOP, SiP, CSP). Further, flip chip mounting processes have started to be used as an effective high-density mounting technique. Sealing materials and underfill materials utilized in these techniques are most frequently resin compositions comprising bisphenol A or F liquid epoxy resins and acid anhydride-based or amine-based curing agents in view of viscosity and heat resistance (glass transition temperature).

However, acid anhydride-based curing agents have a problem in that the cured sealants are hydrolyzed in the presence of hot water, for example, under pressure cooker test conditions, and the formed acid corrodes substrates and wires made from metal such as copper and aluminum, resulting in a decrease in moisture resistant life. Further, amine-based curing agents exhibit so high activity that the reaction is difficult to control.

On the other hand, solutions of semisolid or solid phenol novolac resins in solvents are conventionally used as phenolic curing agents. Further, liquid phenol novolac resins are disclosed: allyl group-containing phenol novolac resins (see, for example, Patent Literatures 1, 2 and 3) and allylation products of phenol novolac resins having a trihydroxyphenylmethane structure (see, for example, Patent Literature 4).

### PRIOR ART LITERATURE

### Patent Literature

Patent Literature 1: JP 2005-075866A

Patent Literature 2: JP 2000-143774A

Patent Literature 3: JP 3794349B

Patent Literature 4: JP 2-91113A

### DISCLOSURE OF THE INVENTION

### Problems to be Solved by the Invention

Because of poor fluidity, however, phenol novolac resins are not suitable as sealants. Solvents are added to improve fluidity. However, the solvents remaining in the cured sealants cause defects such as voids, thus adversely affecting reliability. Allyl group-containing phenol novolac resins exhibit good fluidity (because they are liquid), but cured products thereof are insufficient in heat resistance. Phenol novolac resins having a trihydroxyphenylmethane structure are not necessarily satisfactory in term of fluidity. Thus, conventional phenol novolac resins cannot satisfy low viscosity and heat resistance of cured products at the same time.

It is an object of the present invention to provide phenolic oligomers exhibiting low viscosity and high heat resistance of cured products at the same time, methods for producing such oligomers, curing agents comprising the phenolic oligomers, epoxy resins and epoxy resin compositions utilizing the oligomers or curing agents, and semiconductor sealing materials and underfill materials comprising the epoxy resin compositions.

### Means to Solve the Problems

The present invention has the following configurations.

[1] A phenolic oligomer of the following general formula (1):

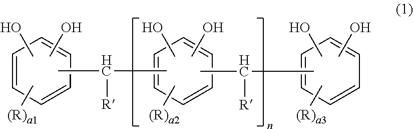

wherein

n is an integer of 0 to 15,

Rs are allyl groups,

a1 and a3 are each independently 0, 1, 2 or 3,

each a2 is independently 0, 1 or 2,

each R′ is independently a hydrogen atom, an alkyl group having 1 to 10 carbon atoms or an aryl group, and

proviso that at least one of a1, each a2 and a3 represents 2.

[2] A method for producing a phenolic oligomer, comprising a step of reacting a phenol compound component comprising at least one dihydric, allyl-substituted phenol compound of the following general formula (2):

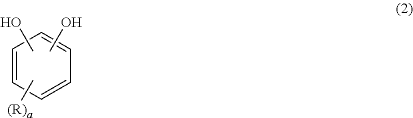

wherein R is an allyl group, and a is 0, 1, 2 or 3, with at least one aldehyde compound of the following general formula (3):

R′CHO (3)

wherein R′ is a hydrogen atom, an alkyl group having 1 to 10 carbon atoms or an aryl group.

[3] The method according to [2], wherein the phenol compound component further comprises at least one monohydric phenol compound of the following general formula (4):

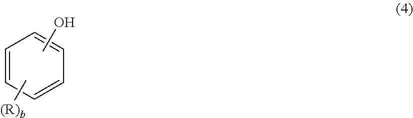

wherein R is an allyl group, and b is 0, 1, 2 or 3.

[4] The method according to [2] or [3], wherein the molar ratio of the phenol compound component(s) to the aldehyde compound is 1.2:1 to 10:1.

[5] The method according to any of [2] to [4], wherein the phenol compound component comprises an allyl-substituted resorcinol.

[6] The method according to any of [2] to [5], wherein the phenol compound component comprises 2,4-diallylresorcinol and 4,6-diallylresorcinol as main components.

[7] The method according to [6], wherein the proportion of 4,6-diallylresorcinol in the phenol compound component is from 15 mol % to 75 mol %.

[8] The method according to any of [2] to [7], wherein the reaction is carried out without catalysts or in the presence of an acid catalyst.

[9] The method according to any of [2] to [8], wherein a dihydric, allyl-substituted phenol compound is used as a phenol compound component which is obtained by allyl-etherifying a hydroxyl group of a dihydric phenol and introducing the allyl group onto the phenol nucleus by Claisen rearrangement.

[10] A phenolic oligomer obtained by the method according to any of [2] to [9].

[11] The phenolic oligomer according to claim [1] or [10], which has a rotational viscosity of 0.01 to 150 Pa·s as measured at 25° C. with an E-type viscometer.

[12] An epoxy resin curing agent comprising the phenolic oligomer according to [1], [10] or [11].

[13] An epoxy resin obtained by a reaction of the phenolic oligomer according to [1], [10] or [11], with an epihalohydrin.

[14] An epoxy resin composition comprising the phenolic oligomer according to [1], [10] or [11], and the epoxy resin according to [13].

[15] An epoxy resin composition comprising a phenol resin, and the epoxy resin according to [13].

[16] An epoxy resin composition comprising the phenolic oligomer according to [1], [10] or [11], and an epoxy resin.

[17] An epoxy resin cured product obtained by curing the epoxy resin composition according to any of [14] to [16].

[18] A sealing material for semiconductor elements comprising the epoxy resin composition according to any of [14] to [16].

[19] An underfill material for semiconductor elements comprising the epoxy resin composition according to any of [14] to [16].

[20] A semiconductor device sealed with the sealing material according to [18] or with the underfill material according to [19].

### Effects of the Invention

According to the present invention, it becomes possible to provide phenolic oligomers exhibiting low viscosity and high heat resistance of cured products at the same time, methods for producing such oligomers, curing agents comprising the phenolic oligomers, epoxy resins and epoxy resin compositions utilizing the oligomers or curing agents, and semiconductor sealing materials and underfill materials comprising the epoxy resin compositions.

### BRIEF DESCRIPTION OF THE DRAWINGS

FIG. 1 illustrates results of HPLC measurement with respect to allyl-substituted resorcinol obtained in Synthetic Example 1.

FIG. 2 illustrates results of GC analysis with respect to a sample (sample 1) fractionated by TLC from a mixture of allyl-substituted resorcinol isomers.

FIG. 3 illustrates results of GC analysis with respect to a sample (sample 2) fractionated by TLC from a mixture of allyl-substituted resorcinol isomers.

FIG. 4 illustrates results of ¹H NMR analysis with respect to the sample 1.

FIG. 5 illustrates results of ¹H NMR analysis with respect to the sample 2.

FIG. 6 illustrates a GPC chart of a phenolic oligomer obtained in Example 1.

### EMBODIMENTS TO CARRY OUT THE INVENTION

### [Phenolic Oligomer]

A phenolic oligomer according to the present invention is of the following general formula (1):

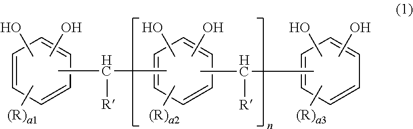

wherein

n is an integer of 0 to 15,

Rs are allyl groups,

a1 and a3 are each independently 0, 1, 2 or 3,

each a2 is independently 0, 1 or 2,

each R′ is independently a hydrogen atom, an alkyl group having 1 to 10 carbon atoms or an aryl group, and

proviso that at least one of a1, each a2 and a3 represents 2. It is preferable that two or more of a1, each a2 and a3 represent 2.

The phenolic oligomer of the above general formula (1) is characterized in that it contains condensed units formed between a dihydric phenol compound substituted with zero, one, two or three allyl groups, preferably one, two or three allyl groups, more preferably one or two allyl groups, and still more preferably two allyl groups (hereinafter, also referred to as dihydric, allyl-substituted phenol compound) and an aldehyde compound. Such phenolic oligomer can exhibit lower viscosity and achieve an improvement in the heat resistance of cured products thereof (as used herein, the term “cured products” indicates cured products obtained by using the phenolic oligomer of the present invention as, for example, curing agents or materials for epoxy resins) compared to conventional condensates between a monohydric phenol compound substituted with one, two or three allyl groups and a formaldehyde compound (for example, Patent Literatures 1 to 4). (Hereinbelow, the capability of increasing the heat resistance of cured products obtained using the phenolic oligomer compounds will be also referred to as heat resistance.)

From the viewpoint of heat resistance, the phenolic oligomer of the above general formula (1) preferably contains structural units derived from dihydric, diallyl phenol compounds (in which a1, a2 and a3 are 2) at 50 to 100 mol %, more preferably 60 to 100 mol %, still more preferably 70 to 100 mol %, even more preferably 80 to 100 mol %, further preferably 90 to 100 mol %, and still further preferably 95 to 100 mol % relative to all the structural units derived from dihydric phenol compounds.

From the viewpoint of heat resistance, the phenolic oligomer of the above general formula (1) may contain structural units derived from dihydric, allyl-free phenol compounds (in which a1, a2 and a3 are 0) to the extent that the presence of such structural units will not excessively increase the viscosity of the phenolic oligomer and will not reduce the heat resistance of cured products made from compositions comprising the oligomer.

In order to make sure that the viscosity of the phenolic oligomer is not excessively increased and to prevent epoxy resin compositions from exhibiting poor fluidity, the degrees of condensation polymerization, indicated by n, are preferably 0 to 10, more preferably 0 to 7, and still more preferably 0 to 5.

For example, the phenolic oligomer of the present invention may be produced by the condensation polymerization of a phenol compound component comprising a dihydric, allyl-substituted phenol compound and an aldehyde compound, or by the condensation polymerization of a dihydric phenol and an aldehyde compound followed by introducing at least two allyl substituents into structural units derived from the phenol compound.

When the phenolic oligomer of the present invention may be used as semiconductor sealing materials and underfill materials, in view of the applicability of the phenolic oligomer, the oligomer is preferably produced by the condensation polymerization of a phenol compound component comprising a dihydric, allyl-substituted phenol compound and an aldehyde compound. When the phenolic oligomer is used in applications where low viscosity is required, it is preferable to produce the phenolic oligomer while controlling its viscosity according to a method for producing phenolic oligomer of the present invention described below.

### [Methods for Producing a Phenolic Oligomer]

A method for producing a phenolic oligomer of the present invention (hereinbelow, also referred to as the production method of the present invention) comprises a step of reacting a phenol compound component comprising at least one dihydric, allyl-substituted phenol compound of the following general formula (2):

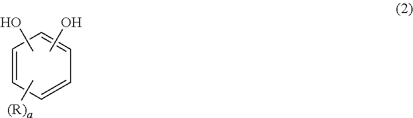

wherein R is an allyl group, and a is 0, 1, 2 or 3, with at least one aldehyde compound of the following general formula (3):

R′CHO (3)

wherein R′ is a hydrogen atom, an alkyl group having 1 to 10 carbon atoms or an aryl group.

In the production method of the present invention, it is preferable that the phenol compound component further comprises at least one monohydric phenol compound of the following general formula (4):

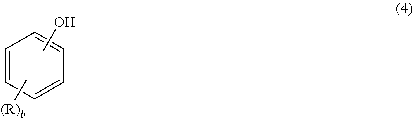

wherein R is an allyl group, and b is 0, 1, 2 or 3.

In the production method of the present invention, from the viewpoints of heat resistance as well as ensuring that the obtainable phenolic oligomer exhibits desired viscosity (hereinbelow, the viewpoint of ensuring that the obtainable phenolic oligomer exhibits desired viscosity is also referred to as the viewpoint of low viscosity), the dihydric, allyl-substituted phenol compound of the general formula (2) is preferably added in a ratio of 50 to 100 mol %, more preferably 60 to 100 mol %, still more preferably 70 to 100 mol %, even more preferably 80 to 100 mol %, further preferably 90 to 100 mol %, and still further preferably 95 to 100 mol % relative to the total amount of the phenol compound component(s) (the amount of at least one dihydric, allyl-substituted phenol compound of the general formula (2), or the total of the amount of at least one dihydric, allyl-substituted phenol compound of the general formula (2) and the amount of at least one monohydric phenol compound of the general formula (4) if any).

That is, from the viewpoints of heat resistance, low viscosity and production efficiency, it is preferable in the production method of the present invention that any phenol compound components other than the dihydric, allyl-substituted phenol compounds of the general formula (2) be monohydric phenol compounds of the general formula (4) and the amount of such compounds added be 0 to 50 mol %, more preferably 0 to 40 mol %, still more preferably 0 to 30 mol %, even more preferably 0 to 20 mol %, further preferably 0 to 10 mol %, and still further preferably 0 to 5 mol % relative to the total amount of the phenol compound components.

In the production method of the present invention, decreasing the amount of the aldehyde compound added relative to the total amount of the phenol compound component(s) results in a phenolic oligomer having low molecular weight and consequently exhibiting low viscosity. Thus, from the viewpoint of low viscosity and further from the viewpoint of ensuring that an epoxy resin cured product obtained from the reaction of the phenolic oligomer and an epoxy resin exhibits appropriate glass transition temperature and mechanical strength, in the production method of the present invention, the material compounds are added such that the molar ratio of the total of the phenol compound component(s) to the aldehyde compound is 1.2:1 to 10:1, preferably 1.3:1 to 9:1, and more preferably 1.4:1 to 8:1.

The dihydric, allyl-substituted phenol compounds of the general formula (2) and the monohydric phenol compounds of the general formula (4) that are used in the production method of the present invention may be obtained by allyl-etherifying a phenolic hydroxyl group of a phenol and introducing the allyl group onto the phenol nucleus by Claisen rearrangement. The material phenol may be a monocyclic phenol having one or two phenolic hydroxyl groups on the benzene ring. Examples include monohydric phenols such as phenol, cresol, ethylphenol, propylphenol, butylphenol, xylenol and butylmethylphenol, and dihydric phenols such as resorcinol, catechol and hydroquinone. Of these materials, resorcinol and catechol, which are dihydric phenols, are preferable, and resorcinol is more preferable from the viewpoint of ensuring that the phenolic oligomer of the present invention exhibit heat resistance.

The allyl-etherification reaction may be carried out by a known method. For example, this reaction may be performed by adding an alkali to a solution of the material phenol in an organic solvent and/or water to form a phenolate, then adding an allyl halide such as allyl chloride, allyl bromide or allyl iodide to the phenolate, and allowing the materials to react with each other at room temperature to 100° C. for 1 to 10 hours.

Examples of the organic solvents used in this reaction include alcohols such as n-propanol and n-butanol, ketones such as acetone and methyl ethyl ketone, and aprotic polar solvents such as N,N-dimethylformamide and dimethylsulfoxide. The allyl-etherification gives a product with a variable yield depending on the solvent used. However, the above organic solvents usually allow the allyl-etherification to proceed with reaction rate of not less than 70%. The solvents may be selected appropriately in accordance with the target reaction rate of phenol, and any solvents able to dissolve the material phenol and the allyl-etherification product may be utilized. Examples of the alkalis include alkali metal hydroxides such as potassium hydroxide and sodium hydroxide. The alkali is used in an amount that is at least equivalent to the phenolic hydroxyl groups to be allyl-etherified. The amount of the allyl halide added is at least equivalent to the alkali.

Next, the allyl-etherified product is heated to about 150 to 250° C. This heating induces Claisen rearrangement, and the allyl group which has been bonded to the hydroxyl group is rearranged onto the phenol nucleus, resulting in an allyl-substituted phenol compound. This allyl group is usually rearranged to an ortho position to the hydroxyl group. The rearrangement allegedly takes place at a para position when there is a substituent such as an alkyl group at the ortho position.

In the production method of the present invention, the phenol compound component comprising at least one dihydric, allyl-substituted phenol compound of the general formula (2) may be a compound obtained from a material dihydric phenol by a reaction such as that described above, or may be a mixture of two or more kinds of such compounds. In the production method of the present invention, the monohydric phenol compound of the general formula (4) that may be used as a phenol compound component may be a compound obtained from a material monohydric phenol by a reaction such as that described above, or may be a mixture of two or more kinds of such compounds. Specific examples of the monohydric, allyl-substituted phenol compounds include allylphenol, diallylphenol and triallylphenol. Examples of the dihydric, allyl-substituted phenol compounds include allyl-substituted catechols such as monoallylcatechol, diallylcatechol and triallylcatechol, allyl-substituted hydroquinones such as monoallylhydroquinone, diallylhydroquinone and triallylhydroquinone, and allyl-substituted resorcinols such as monoallylresorcinol, diallylresorcinol and triallylresorcinol. From the viewpoints of low viscosity and heat resistance, allyl-substituted resorcinols, specifically monoallylresorcinol, diallylresorcinol and triallylresorcinol are preferable, with diallylresorcinol being preferable. Trihydric, allyl-substituted phenol compounds (such as monoallylpyrogallol and diallylpyrogallol) may be used to the extent that they will not undermine the effects of the present invention.

For example, resorcinol may be subjected to allyl-etherification with respect to the hydroxyl groups and subsequently to Claisen rearrangement. This gives a mixture of dihydric, allyl-substituted phenol compounds which comprises, as main components, two kinds of isomers, namely, 2,4-diallylresorcinol and 4,6-diallylresorcinol. (The mixture may comprise minor components such as mono- or triallyl compounds.) In this case, the mixture of dihydric, allyl-substituted phenol compounds comprising two kinds of isomers as main components may be separated into individual isomers, and each isomer may be used individually. Alternatively, the mixture which comprises, as main components, these isomers may be used as such without any problems. From the viewpoint of productivity, it is preferable that the mixture which comprises, as main components, the above isomers be used directly. Here, the phrase “comprises, as main components, two kinds of isomers” or “comprising two kinds of isomers as main components ” indicates that the total amount of the two kinds of isomers is 50 to 100 mol %, preferably 60 to 100 mol %, more preferably 70 to 100 mol %, even more preferably 80 to 100 mol %, particularly preferably 90 to 100 mol %, and still further preferably 95 to 100 mol % relative to the total amount of the dihydric, allyl-substituted phenol compounds. In the case where the phenol compound components used are the mixture which comprises, as main components, two kinds of isomers, namely, 2,4-diallylresorcinol and 4,6-diallylresorcinol, it is preferable that the proportion of 4,6-diallylresorcinol be lower because the phenolic oligomer of the present invention exhibits low viscosity. In such phenol compound components, the proportion of 4,6-diallylresorcinol is preferably 5 to 85 mol %, more preferably 10 to 80 mol %, and still more preferably 15 to 75 mol %.

From the viewpoints of heat resistance and low viscosity, the aldehyde compound used in the production method of the present invention is preferably such that R₃ is a hydrogen atom or an alkyl group having 1 to 10 carbon atoms, and is more preferably a hydrogen atom. That is, formaldehyde is a more preferred aldehyde compound. Specific examples include formaldehydes such as aqueous formalin solution and paraformaldehyde, alkylaldehydes such as hexanal and octanal, and aromatic aldehyde compounds such as benzaldehyde, salicylaldehyde, para-hydroxybenzaldehyde and allylphenylaldehyde. These aldehyde compounds may be used singly, or plural compounds may be used without any problems. From the viewpoints of easy handling and low viscosity, the aldehyde compound is preferably an aqueous foinialin solution which can be handled easily. A commercial 42% aqueous formaldehyde solution may be used directly.

In the production method of the present invention, the condensation polymerization reaction may be carried out without catalysts or in the presence of an acid catalyst. The acid catalyst used in the reaction is not particularly limited, and any known acid catalysts such as hydrochloric acid, oxalic acid, sulfuric acid, phosphoric acid and para-toluenesulfonic acid may be used. The catalysts may be used singly, or two or more kinds may be used in combination. When the acid catalyst is used, oxalic acid or hydrochloric acid is preferable because such catalysts can be removed easily.

In the production method of the present invention, the acid catalyst may be preferably used in an amount of 0.001 to 5.0 parts by weight, more preferably 0.001 to 2.5 parts by weight, and still more preferably 0.001 to 2.0 parts by weight with respect to 100 parts by weight of the phenol compound component. This amount ensures an appropriate reaction rate for controlling the reaction.

In the production method of the present invention, the reaction temperature is preferably 50 to 160° C., and more preferably 70 to 150° C. in order to ensure that the aldehyde compound is reacted smoothly and an appropriate reaction rate for controlling the reaction is obtained. The reaction time is variable depending on the reaction temperature, and the type and amount of the catalyst used, but is preferably 1 to 24 hours, more preferably 1 to 20 hours, and still more preferably 1 to 16 hours. The reaction pressure is usually normal pressure. However, the reaction may be performed under increased or reduced pressure without any problems.

In the production method of the present invention, it is not always necessary that unreacted allyl-substituted phenol compounds be removed. When such unreacted allyl-substituted phenol compounds are removed, a usual method is to distill away the unreacted compounds from the system by heating under reduced pressure or while blowing an inert gas. The acid catalyst may be removed by thermal decomposition or vacuum removal, as well as by being washed with water or the like.

From the viewpoint of heat resistance, a purity of phenolic oligomer obtained by the production method of the present invention is desirably 100 wt %. In view of production efficiency, however, the oligomer may comprise unreacted materials or trace amounts of byproducts to the extent that the heat resistance effect according to the present invention is not undetermined. In such cases, the purity of the phenolic oligomer composition obtained is preferably 70 to 100 wt %, more preferably 80 to 100 wt %, still more preferably 90 to 100 wt %, and further preferably 95 to 100 wt %. The purity may be calculated by GPC measurement as will be described later.

From the viewpoint of low viscosity, the phenolic oligomer of the general formula (1) and the phenolic oligomer obtained by the production method of the present invention have a rotational viscosity of 0.01 to 100 Pa·s, preferably 0.01 to 50 Pa·s, more preferably 0.01 to 40 Pa·s, still more preferably 0.01 to 30 Pa·s, further preferably 0.01 to 20 Pa·s, furthermore preferably 0.01 to 10 Pa·s, still further preferably 0.01 to 5 Pa·s, and even further preferably 0.01 to 3 Pa·s as measured at 70° C. with an E-type viscometer.

From the viewpoint of low viscosity, further, the phenolic oligomer of the general formula (1) and the phenolic oligomer obtained by the production method of the present invention preferably have a rotational viscosity of 0.01 to 150 Pa·s, more preferably 0.01 to 130 Pa·s, still more preferably 0.01 to 100 Pa·s, even more preferably 0.01 to 80 Pa·s, further preferably 0.01 to 70 Pa·s, and furthermore preferably 0.01 to 60 Pa·s as measured at 25° C. with an E-type viscometer.

When a phenolic oligomer of the general formula (1) is obtained by the production method of the present invention, the condensation polymerization is preferably controlled such that the degrees of condensation polymerization of the phenolic oligomer, indicated by the letter n, become 0 to 15, preferably 0 to 10, more preferably 0 to 7, and still more preferably 0 to 4, as well as that the average degree of condensation polymerization of the phenolic oligomer becomes 0 to 5, preferably 0 to 4, and more preferably 0 to 3. Such controlling ensures that the rotational viscosity of the phenolic oligomer according to an E-type viscometer falls in the aforementioned range. In detail, the degrees of condensation polymerization and the average degree of condensation polymerization may be controlled to be in the above preferred ranges by adding the phenol compound component, in particular the dihydric, allyl-substituted phenol compound, and formaldehyde in a molar ratio of 1.2:1 to 10:1, preferably 1.3:1 to 9:1, and more preferably 1.4:1 to 8:1.

The degrees of condensation polymerization and the average degree of condensation polymerization may be determined by GPC measurement as will be described later.

### [Epoxy Resins and Epoxy Resin Compositions]

The phenolic oligomer of the general formula (1) and the phenolic oligomer obtained by the production method of the present invention (hereinafter, these may be collectively referred to as “the phenolic oligomers of the present invention”) may be used directly as epoxy resin curing agents in various applications such as binders, coating materials, laminating materials and molding materials.

The phenolic oligomers of the present invention may be reacted with an epihalohydrin to form an epoxy resin (i).

As an example, a reaction will be discussed in which the inventive phenolic oligomers of the present invention are reacted with epichlorohydrin as the epihalohydrin to give an epoxy resin (i). In this case, for example, epichlorohydrin is added in excess to the phenolic oligomers of the present invention, and they are reacted with each other in the presence of an alkali metal hydroxide such as sodium hydroxide or potassium hydroxide at 50 to 150° C., preferably 60 to 120° C., for about 1 to 10 hours. The molar amount of epichlorohydrin used is 2 to 15 times, and preferably 2 to 10 times the hydroxyl equivalent of the phenolic oligomers of the present invention. The molar amount of the alkali metal hydroxide used is 0.8 to 1.2 times, and preferably 0.9 to 1.1 times the hydroxyl equivalent of the phenolic oligomers of the present invention. Posttreatment may be performed after the reaction. After the completion of the reaction, the excess epichlorohydrin may be distilled away, the residue may be dissolved in an organic solvent such as methyl isobutyl ketone, filtered and washed with water to remove inorganic salts, and the organic solvent may be distilled away, thus obtaining the target epoxy resin.

Examples of the epihalohydrins usable for the reaction with the phenolic oligomers of the present invention include epichlorohydrin, α-methylepichlorohydrin, γ-methylepichlorohydrin and epibromohydrin. Epichlorohydrin is preferably used because it is easily available in industry and exhibits good reactivity with the hydroxyl groups of the phenolic oligomers of the present invention.

The phenolic oligomers of the present invention may be mixed together with the epoxy resin (i) to give an epoxy resin composition (I). Curing accelerators and other additives may be added to the epoxy resin composition (I).

The epoxy resin (i) may be mixed together with a phenol resin to give an epoxy resin composition (II). Curing accelerators and other additives may be added to the epoxy resin composition (II).

Since the epoxy resin (i) has low viscosity, the epoxy resin composition is also resulted in low viscosity. In view of this, the phenol resin used in the epoxy resin composition (II) is preferably any of phenol novolac resins, cresol novolac resins, phenol aralkyl resins, biphenyl aralkyl resins, naphthol novolac resins, cashew novolac resins and allylphenol novolac resins, more preferably any of phenol novolac resins, cresol novolac resins, phenol aralkyl resins, biphenyl aralkyl resins and allylphenol novolac resins, and still more preferably any of phenol novolac resins, phenol aralkyl resins, biphenyl aralkyl resins and allylphenol novolac resins.

The phenolic oligomer may be mixed with an epoxy resin (ii) to give an epoxy resin composition (III). Examples of the epoxy resins (ii) include epoxy resins having two or more epoxy groups per molecule such as glycidyl ether epoxy resins, glycidyl ester epoxy resins, glycidyl amine epoxy resins and halogenated epoxy resins, with specific examples including bisphenol A epoxy resins, bisphenol F epoxy resins, cresol novolac epoxy resins, phenol novolac epoxy resins, triphenolmethane epoxy resins and biphenyl epoxy resins. These epoxy resins may be used singly, or two or more kinds may be used in combination without any problems. In order to reduce the viscosity of the epoxy resin composition, preferred epoxy resins are bisphenol A epoxy resins which are preferably liquid at 70° C., more preferably 25° C., and bisphenol F epoxy resins which are preferably liquid at 70° C., more preferably 25° C. Curing accelerators and other additives may be added to the epoxy resin composition (III).

Curing accelerators may be added to the epoxy resin compositions (I) to (III) (hereinbelow, these may be collectively referred to as “the epoxy resin compositions of the present invention”). Known curing accelerators capable of bringing about the curing reaction of epoxy resins with phenol resins may be used. Examples of the curing accelerators include organic phosphine compounds and borates thereof, tertiary amines, quaternary ammonium salts, and imidazoles and tetraphenylborates thereof. Of these, 2-ethyl-4-methylimidazole which is liquid at 25° C. is preferable from the viewpoints of curing properties and viscosity reduction.

Where necessary, additives such as inorganic fillers, release agents, colorants, coupling agents and flame retardants may be added to the epoxy resin compositions of the present invention. In particular, the addition of inorganic fillers is essential when the compositions are used in semiconductor sealing applications. Examples of the inorganic fillers include amorphous silica, crystalline silica, alumina, calcium silicate, calcium carbonate, talc, mica and barium sulfate. In particular, such fillers as amorphous silica and crystalline silica are preferable. The additives may be added at proportions similar to those in known semiconductor-sealing epoxy resin compositions.

Exemplary semiconductor sealants include sealing materials that provide a seal in gaps between semiconductor elements and circuit boards as well as a seal around the semiconductor elements, and underfill materials that provide only a seal in gaps between semiconductor elements and circuit boards. The sealants may be liquids, pastes or solids such as tablets.

For example, the epoxy resin compositions of the present invention may be allowed to react at 100 to 350° C. and be cured to give an epoxy resin cured product. A semiconductor device may be obtained by sealing a semiconductor with the epoxy resin compositions of the present invention. Such semiconductor devices may be obtained by a method in which an underfill material comprising the epoxy resin composition is poured into a gap between a semiconductor and a circuit board and the epoxy resin composition is cured, or by a method in which a sealing material comprising the epoxy resin composition is poured into a gap between a semiconductor and a circuit board as well as around the semiconductor and the epoxy resin composition is cured. In the present invention, sealing of semiconductor elements comprises a step of pouring an underfill material into a gap between a semiconductor element and a circuit board, and a step of curing the underfill material, or comprises a step of pouring a sealing material into a gap between a semiconductor element and a circuit board as well as around the semiconductor, and a step of curing the sealing material.

Hereinbelow, the present invention will be described in more detail by illustrating examples and comparative examples. However, the scope of the present invention is not limited to such examples. In examples, “part(s)” refers to part(s) by weight.

### EXAMPLES

### Synthetic Example 1

### [Synthesis of Allyl-Substituted Resorcinol]

A four-necked glass flask equipped with a thermometer, a feed inlet, a distillate outlet, a condenser and a stirrer was charged with 100.0 parts (2.4 mol) of sodium hydroxide and 600 ml of N,N-dimethylformamide. Then, a solution of 110.1 parts (1.0 mol) of resorcinol in 500 ml of N,N-dimethylformamide was added dropwise. Further, 191.3 parts (2.4 mol) of allyl chloride and 300 ml of N,N-dimethylformamide were added dropwise, and the reaction was performed at 30° C. for 6 hours. The reaction liquid was neutralized with hydrochloric acid, washed with water several times, and subjected to reduced pressure at 150° C., thereby removing the solvent and distilling the target compound. Thus, 255.0 parts of allyl-etherified resorcinol was obtained.

The resulting allyl-etherified resorcinol, 255.0 parts, was subjected to Claisen rearrangement at 190° C. for 3 hours. Thus, 250.0 parts of allyl-substituted resorcinol (dihydric, allyl-substituted phenol compound) was obtained as a yellow brown liquid. HPLC analysis (see (1) in (Methods of analysis for allyl-substituted phenol compounds)) showed that the resulting allyl-substituted resorcinol had a purity of 93% and the proportion of 4,6-diallyl isomer was 48% (% based on peak areas).

### Synthetic Example 2

### [Synthesis of Allyl-Substituted Resorcinol]

A four-necked glass flask equipped with a thermometer, a feed inlet, a distillate outlet, a condenser and a stirrer was charged with 196.0 parts (4.8 mol) of sodium hydroxide and 1200 ml of N,N-dimethylformamide. Then, a solution of 220.2 parts (2.0 mol) of resorcinol in 1000 ml of N,N-dimethylformamide was added dropwise. Further, 382.7 parts (4.8 mol) of allyl chloride and 600 ml of N,N-dimethylformamide were added dropwise, and the reaction was performed at 30° C. for 6 hours. The reaction liquid was neutralized with hydrochloric acid, washed with water several times, and subjected to reduced pressure at 150° C., thereby removing the solvent and purifying the target compound by distillation. Thus, 490.0 parts of allyl-etherified resorcinol was obtained.

The resulting allyl-etherified resorcinol, 490.0 parts, was subjected to Claisen rearrangement at 190° C. for 4 hours. Of the resulting allyl-substituted resorcinol, a 300 part portion was purified by distillation using a Vigreux column at 160° C. under vacuum of 5 mmHg. Approximately 30 parts of the initial distillate was removed, and then 70.0 parts of allyl-substituted resorcinol (dihydric, allyl-substituted phenol compound) was obtained.

HPLC analysis (similar to Synthetic Example 1) showed that the allyl-substituted resorcinol was a transparent liquid with 90% purity and the proportion of 4,6-diallyl isomer was 29%.

### Synthetic Example 3

### [Synthesis of Allyl-Substituted Resorcinol]

The residue from the purification by distillation in Synthetic Example 2 was further purified by distillation at 165° C. under vacuum of 5 mmHg. Thus, 110.0 parts of allyl-substituted resorcinol was obtained.

HPLC analysis (similar to Synthetic Example 1) showed that the allyl-substituted resorcinol was a transparent liquid with 89% purity and the proportion of 4,6-diallyl isomer was 43%.

### Synthetic Example 4

### [Synthesis of Allyl-Substituted Resorcinol]

The residue from the purification by distillation in Synthetic Example 3 was further purified by distillation at 175° C. under vacuum of 3 mmHg Thus, 60.0 parts of allyl-substituted resorcinol (dihydric, allyl-substituted phenol compound) was obtained.

HPLC analysis (similar to Synthetic Example 1) showed that the allyl-substituted resorcinol was a transparent liquid with 88% purity and the proportion of 4,6-diallyl isomer was 65%.

### Synthetic Example 5

### [Synthesis of Allyl-Substituted Resorcinol]

A four-necked glass flask equipped with a thermometer, a feed inlet, a distillate outlet, a condenser and a stirrer was charged with 49.0 parts (1.2 mol) of sodium hydroxide and 300 ml of N,N-dimethylformamide Then, a solution of 55.1 parts (0.5 mol) of resorcinol in 250 ml of N,N-dimethylformamide was added dropwise. Further, 95.7 parts (1.2 mol) of allyl chloride and 150 ml of N,N-dimethylfoimamide were added dropwise, and the reaction was performed at 30° C. for 6 hours. The reaction liquid was neutralized with hydrochloric acid, washed with water several times, and subjected to reduced pressure at 150° C., thereby removing the solvent and distilling the target compound. Thus, allyl-etherified resorcinol was obtained.

The resulting allyl-etherified resorcinol, 125.0 parts, was subjected to Claisen rearrangement at 185° C. for 4.5 hours. The resulting allyl-substituted resorcinol was purified by distillation using a Vigreux column at 160° C. under vacuum of 4 mmHg Approximately 20 parts of the initial distillate was removed, and then 50.0 parts of allyl-substituted resorcinol (dihydric, allyl-substituted phenol compound) was obtained.

HPLC analysis (similar to Synthetic Example 1) showed that the allyl-substituted resorcinol was a transparent liquid with 97% purity and the proportion of 4,6-diallyl isomer was 23%.

### Synthetic Example 6

### [Synthesis of Allyl-Substituted Catechol]

A four-necked glass flask equipped with a thermometer, a feed inlet, a distillate outlet, a condenser and a stirrer was charged with 375.2 parts (2.7 mol) of potassium carbonate, 100.9 parts (0.9 mol) of catechol and 1000 ml of acetone. Then, 280.8 parts (2.3 mol) of allyl bromide and 260 ml of acetone were added dropwise, and the reaction was performed at 60° C. for 13 hours. Then, the reaction liquid was combined with 500 ml of acetone, filtered, concentrated, washed with water several times, and subjected to reduced pressure at 80° C. Thus, allyl-etherified catechol was obtained.

To 100.0 parts of the resulting allyl-etherified catechol were added 40.0 parts of diglyme and 2.0 parts of zinc chloride. The allyl-etherified catechol was then subjected to Claisen rearrangement at 160° C. for 7 hours, then purified by distillation to give 75.4 parts of allyl-substituted catechol (dihydric, allyl-substituted phenol compound).

HPLC analysis (similar to Synthetic Example 1) showed that the allyl-substituted catechol was a colorless transparent liquid with 87% purity.

### Example 1

### [Synthesis of Phenolic Oligomer]

A four-necked glass flask equipped with a thermometer, a feed inlet, a distillate outlet, a condenser and a stirrer was charged with 28.5 parts (0.15 mol) of the allyl-substituted resorcinol from Synthetic Example 1 and 5.4 parts (0.08 mol) of 42% formalin. The reaction was carried out at 100° C. for 8 hours. Thereto were added 63.0 parts of pure water heated to at least 90° C. to wash the reaction liquid. Then, the temperature was raised to 120° C., and the water and unreacted components were removed by vacuum treatment.

Gel permeation chromatography (see (7) in (Methods of analysis for phenolic oligomers and cured products) showed that the resulting phenolic oligomer had a purity of 96.2 wt %, degrees (n) of condensation polymerization of 0 to 4, and an average degree of condensation polymerization of 0.8. The phenolic oligomer was liquid at 70° C. and 25° C., and exhibited a rotational viscosity of 0.54 Pa·s at 70° C. and 89 Pa·s at 25° C. (see (1) in the same section).

### Example 2

### [Synthesis of Phenolic Oligomer]

A four-necked glass flask equipped with a thermometer, a feed inlet, a distillate outlet, a condenser and a stirrer was charged with 57.0 parts (0.30 mol) of the allyl-substituted resorcinol from Synthetic Example 1, 10.7 parts (0.15 mol) of 42% formalin, and 0.6 parts of oxalic acid as an acid catalyst. The reaction was carried out at 100° C. for 4 hours. Thereto were added 125.0 parts of pure water heated to at least 90° C. to wash the reaction liquid. Then, the temperature was raised to 120° C., and the water and unreacted components were removed by vacuum treatment.

Gel permeation chromatography (similar to Example 1) showed that the resulting phenolic oligomer had a purity of 98.5 wt %, degrees (n) of condensation polymerization of 0 to 4, and an average degree of condensation polymerization of 0.6. The phenolic oligomer was liquid at 70° C. and 25° C., and exhibited a rotational viscosity of 0.55 Pa·s at 70° C. and 91 Pa·s at 25° C. (similar to Example 1).

### Example 3

### [Synthesis of Phenolic Oligomer]

A four-necked glass flask equipped with a thermometer, a feed inlet, a distillate outlet, a condenser and a stirrer was charged with 57.0 parts (0.30 mol) of the allyl-substituted resorcinol from Synthetic Example 1, 5.4 parts (0.08 mol) of 42% formalin, and 0.6 parts of oxalic acid as an acid catalyst. The reaction was carried out at 100° C. for 4 hours. Thereto were added 125.0 parts of pure water heated to at least 90° C. to wash the reaction liquid. Then, the temperature was raised to 120° C., and the water and unreacted components were removed by vacuum treatment.

Gel permeation chromatography (similar to Example 1) showed that the resulting phenolic oligomer had a purity of 69.7 wt %, degrees (n) of condensation polymerization of 0 to 4, and an average degree of condensation polymerization of 0.5. The phenolic oligomer was liquid at 70° C. and 25° C., and exhibited a rotational viscosity of 0.05 Pa·s at 70° C. and 1.6 Pa·s at 25° C. (similar to Example 1).

### Example 4

### [Synthesis of Phenolic Oligomer]

A four-necked glass flask equipped with a thermometer, a feed inlet, a distillate outlet, a condenser and a stirrer was charged with 16.7 parts (0.08 mol) of the allyl-substituted resorcinol from Synthetic Example 1, 4.2 parts (0.05 mol) of 42% formalin, and 0.2 parts of concentrated hydrochloric acid as an acid catalyst. The reaction was carried out at 100° C. for 1 hour. Thereto were added 50.0 parts of pure water heated to at least 90° C. to wash the reaction liquid. Then, the temperature was raised to 120° C., and the water and unreacted components were removed by vacuum treatment.

Gel permeation chromatography (similar to Example 1) showed that the resulting phenolic oligomer had a purity of 98.3 wt %, degrees (n) of condensation polymerization of 0 to 4, and an average degree of condensation polymerization of 0.7. The phenolic oligomer was liquid at 70° C. and 25° C., and exhibited a rotational viscosity of 0.65 Pa·s at 70° C. and 124 Pa·s at 25° C. (similar to Example 1).

### Example 5

### [Synthesis of Phenolic Oligomer]

A four-necked glass flask equipped with a thermometer, a feed inlet, a distillate outlet, a condenser and a stirrer was charged with 380.0 parts (2.00 mol) of the allyl-substituted catechol from Synthetic Example 6, 7.1 parts (0.1 mol) of 42% formalin, and 7.6 parts of oxalic acid as an acid catalyst. The reaction was carried out at 100° C. for 24 hours. Thereto were added 500.0 parts of pure water heated to at least 90° C. to wash the reaction liquid. Then, the temperature was raised to 180° C. to remove water, and unreacted components were removed by vacuum steam treatment.

Gel permeation chromatography (similar to Example 1) showed that the resulting phenolic oligomer had a purity of 95.7 wt %, degrees (n) of condensation polymerization of 0 to 6, and an average degree of condensation polymerization of 1.2. The phenolic oligomer was liquid at 70° C. and viscous solid at 25° C., and exhibited a rotational viscosity of 14.3 Pa·s at 70° C. and at least 107 Pa·s at 25° C. (similar to Example 1).

### Example 6

### [Synthesis of Phenolic Oligomer]

A four-necked glass flask equipped with a thermometer, a feed inlet, a distillate outlet, a condenser and a stirrer was charged with 57.0 parts (0.30 mol) of the allyl-substituted resorcinol from Synthetic Example 3, 10.7 parts (0.15 mol) of 42% formalin, and 0.6 parts of oxalic acid as an acid catalyst. The reaction was carried out at 100° C. for 4 hours. Thereto were added 125.0 parts of pure water heated to at least 90° C. to wash the reaction liquid. Then, the temperature was raised to 120° C., and the water and unreacted components were removed by vacuum treatment.

Gel permeation chromatography (similar to Example 1) showed that the resulting phenolic oligomer had a purity of 97.9 wt %, degrees (n) of condensation polymerization of 0 to 4, and an average degree of condensation polymerization of 0.6. The phenolic oligomer was liquid at 70° C. and 25° C., and exhibited a rotational viscosity of 0.32 Pa·s at 70° C. and 32 Pa·s at 25° C. (similar to Example 1).

### Example 7

### [Synthesis of Phenolic Oligomer]

A four-necked glass flask equipped with a thermometer, a feed inlet, a distillate outlet, a condenser and a stirrer was charged with 57.0 parts (0.30 mol) of the allyl-substituted resorcinol from Synthetic Example 2, 10.7 parts (0.15 mol) of 42% formalin, and 0.6 parts of oxalic acid as an acid catalyst. The reaction was carried out at 100° C. for 4 hours. Thereto were added 125.0 parts of pure water heated to at least 90° C. to wash the reaction liquid. Then, the temperature was raised to 120° C., and the water and unreacted components were removed by vacuum treatment.

Gel permeation chromatography (similar to Example 1) showed that the resulting phenolic oligomer had a purity of 98.5 wt %, degrees (n) of condensation polymerization of 0 to 4, and an average degree of condensation polymerization of 0.5. The phenolic oligomer was liquid at 70° C. and 25° C., and exhibited a rotational viscosity of 0.28 Pa·s at 70° C. and 26 Pa·s at 25° C. (similar to Example 1).

### Example 8

### [Synthesis of Phenolic Oligomer]

A four-necked glass flask equipped with a thermometer, a feed inlet, a distillate outlet, a condenser and a stirrer was charged with 45.6 parts (0.24 mol) of the allyl-substituted resorcinol from Synthetic Example 4, 8.6 parts (0.12 mol) of 42% formalin, and 0.5 parts of oxalic acid as an acid catalyst. The reaction was carried out at 100° C. for 4 hours. Thereto were added 100.0 parts of pure water heated to at least 90° C. to wash the reaction liquid. Then, the temperature was raised to 120° C., and the water and unreacted components were removed by vacuum treatment.

Gel permeation chromatography (similar to Example 1) showed that the resulting phenolic oligomer had a purity of 98.2 wt %, degrees (n₁) of condensation polymerization of 0 to 4, and an average degree (n₂) of condensation polymerization of 0.6. The phenolic oligomer was liquid at 70° C. and 25° C., and exhibited a rotational viscosity of 0.51 Pa·s at 70° C. and 72 Pa·s at 25° C.

### Example 9

### [Synthesis of Phenolic Oligomer]

A four-necked glass flask equipped with a thermometer, a feed inlet, a distillate outlet, a condenser and a stirrer was charged with 41.8 parts (0.22 mol) of the allyl-substituted resorcinol from Synthetic Example 5, 7.9 parts (0.11 mol) of 42% formalin, and 0.4 parts of oxalic acid as an acid catalyst. The reaction was carried out at 100° C. for 4 hours. Thereto were added 100.0 parts of pure water heated to at least 90° C. to wash the reaction liquid. Then, the temperature was raised to 120° C., and the water and unreacted components were removed by vacuum treatment.

Gel permeation chromatography (similar to Example 1) showed that the resulting phenolic oligomer had a purity of 98.2 wt %, degrees (n) of condensation polymerization of 0 to 4, and an average degree of condensation polymerization of 0.5. The phenolic oligomer was liquid at 70° C. and 25° C., and exhibited a rotational viscosity of 0.25 Pa·s at 70° C. and 25 Pa·s at 25° C. (similar to Example 1).

### Comparative Example 1

A four-necked glass flask equipped with a thermometer, a feed inlet, a distillate outlet, a condenser and a stirrer was charged with 670 parts (5.0 mol) of o-allylphenol, 71.4 parts (1.0 mol) of 42% formalin, and 6.7 parts of oxalic acid as an acid catalyst. The reaction was carried out at 100° C. for 5 hours. Thereto were added 00 parts of pure water heated to at least 90° C. to wash the reaction liquid. Then, the temperature was raised to 165° C. to remove water, and unreacted components were removed by vacuum treatment. The resulting phenol compound composition was liquid at 70° C. and 25° C., and exhibited a rotational viscosity of 0.07 Pa·s at 70° C. and 1.7 Pa·s at 25° C. (similar to Example 1).

### Comparative Example 2

A polyalkenyl compound (a phenol novolac resin having a tris(hydroxyallylphenyl)methane structure) was synthesized based on Example in Patent Literature 4 cited in this invention.

[symbol]

Synthesis of Phenol Novolac Resin Having tris(hydroxyphenyl)methane Structure

[symbol]

A four-necked glass flask equipped with a thermometer, a feed inlet, a distillate outlet, a condenser and a stirrer was charged with 400 parts (4.26 mol) of phenol, 47.2 parts (0.38 mol) of salicylaldehyde and 1.0 part of para-toluenesulfonic acid. The reaction was carried out at 130° C. under a stream of nitrogen. The reaction liquid was cooled to 95° C., neutralized with a 25% aqueous sodium hydroxide solution, and washed with 400.0 parts of pure water which had been heated to at least 90° C. Then, the internal temperature was raised to 150° C., and unreacted components were removed by vacuum steam treatment. The obtained resin was solid at 70° C. and 25° C., and exhibited a melt viscosity of 0.9 Pa·s at 150° C.

[symbol]

Allylation to Synthesize Phenol Novolac Resin Having tris(hydroxyallylphenyl)methane Structure

[symbol]

A four-necked glass flask equipped with a thermometer, a feed inlet, a distillate outlet, a condenser and a stirrer was charged with 100.0 parts of the phenol novolac resin having a tris(hydroxyphenyl)methane structure produced above, and 250.0 parts of 2-propanol. After the resin was dissolved to give a homogenous solution, 40.7 parts (1.02 mol) of sodium hydroxide was added and the mixture was stirred for 1 hour continuously. Thereto were added 79.6 parts (1.02 mol) of allyl chloride dropwise within 10 minutes, and then the reaction was carried out at 75° C. for 5 hours, thereby allyl-etherifying the resin. After 2-propanol was removed, the byproduct sodium chloride was washed by the addition of 500.0 parts of pure water which had been heated to at least 90° C. Then, the temperature was raised to 190° C. to remove water, and Claisen rearrangement was performed for 6 hours. The resulting resin was liquid at 70° C. and semisolid at 25° C., and exhibited a rotational viscosity of 1.1 Pa·s at 70° C. and at least 107 Pa·s at 25° C. (similar to Example 1).

### Comparative Example 3

[symbol] Synthesis of Resorcinol Novolac Resin

[symbol]

A four-necked glass flask equipped with a thermometer, a feed inlet, a distillate outlet, a condenser and a stirrer was charged with 660 parts (6.00 mol) of resorcinol, 42.4 parts (0.60 mol) of 42% fon ialin, and 0.2 parts of oxalic acid as an acid catalyst. The reaction was carried out at 100° C. for 5 hours. Thereto were added 500.0 parts of pure water heated to at least 90° C. to wash the reaction liquid. Then, the temperature was raised to 170° C. to remove water, and unreacted components were removed by vacuum steam treatment. The resulting resorcinol novolac resin was solid, and exhibited a melt viscosity of 0.07 Pa·s at 150° C.

[symbol]

Allylation of Resorcinol Novolac Resin

[symbol]

A four-necked glass flask equipped with a thermometer, a feed inlet, a distillate outlet, a condenser and a stirrer was charged with 50.0 parts of the resorcinol produced above, and 100.0 parts of 2-propanol. After the resin was dissolved to give a homogenous solution, 36.5 parts (0.91 mol) of sodium hydroxide was added and the mixture was stirred for 1 hour continuously. Thereto were added 75.0 parts (0.96 mol) of allyl chloride dropwise within 10 minutes, and the reaction was carried out at 60° C. for 5 hours, thereby allyl-etherifying the resin. After 2-propanol was removed, the byproduct sodium chloride was washed by the addition of 500.0 parts of pure water which had been heated to at least 90° C. Then, the temperature was raised to 190° C. to remove water, and Claisen rearrangement was performed for 6 hours. The obtained resin was solid at 70° C. and 25° C., and exhibited a melt viscosity of at least 10 Pa·s at 150° C.

[symbol]

Methods of Analysis for Allyl-Substituted Phenol Compounds

[symbol]

### (1) HPLC

High performance liquid chromatography (HPLC) was performed under the following conditions to determine the purity of the allyl-substituted phenol compounds as well as the isomer proportion of 2,4-diallyl isomer and 4,6-diallyl isomer.

Column: ODS-80Ts 250×4.6 mm

Detection method: visible detector (UV 254 nm)

Mobile phase: acetonitrile/water=60/40

Flow rate: 1.0 ml/min

Column temperature: 40° C.

Sample preparation: A sample liquid weighing 0.2 g was diluted with 40 g of acetonitrile, and a 20 μL portion was injected.

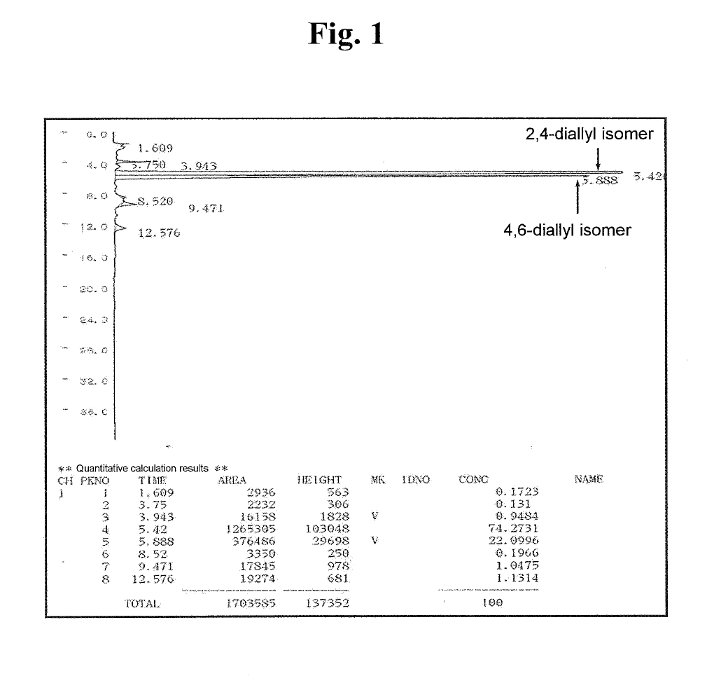

As an example of the HPLC measurement results, the results in Synthetic Example 5 are illustrated in FIG. 1. In the figure, the peak at a retention time of approximately 5.4 minutes was assigned to 2,4-diallyl isomer, and the peak at a retention time of approximately 5.9 minutes was assigned to 4,6-diallyl isomer.

The purity of the allyl-substituted phenol compound was calculated to be 96% based on the proportion of the total of the areas of these two peaks relative to the total peak area.

By dividing the respective peak areas by the purity, the proportion of 2,4-diallyl isomer was calculated to be 77% and that of 4,6-diallyl isomer to be 23%.

### (2) Identification of Allyl-Substituted Isomers

The allyl-substituted phenol compound (the allyl-substituted resorcinol) was fractionated by thin-layer chromatography (TLC) under the following conditions to give two samples.

### TLC Fractionation Conditions

TLC 1 mm (Silica gel 60 F254 PLC Plates)

Developing solvent: hexane/ethyl acetate=2/1

The two samples were analyzed by GC and ¹H NMR to identify the allyl-substituted resorcinol isomers.

### GC Conditions

Column: G-100 1.2 mm I.D.×40 m, film thickness 1.0 μm

Column temperature and heating conditions: Temperature was increased from 100° C. to 200° C. at 4° C./min, and held for 15 minutes.

Injection/detection temperature: 250° C.

Gas pressures: He=100 kPa, Air=50 kPa, H₂=65 kPa

Sample preparation: The reaction liquid was filtered, and a 0.1 μL portion was injected.

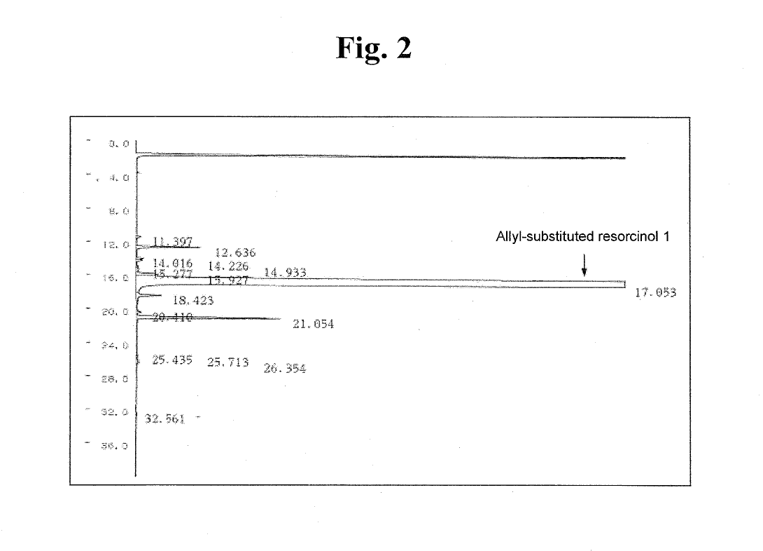

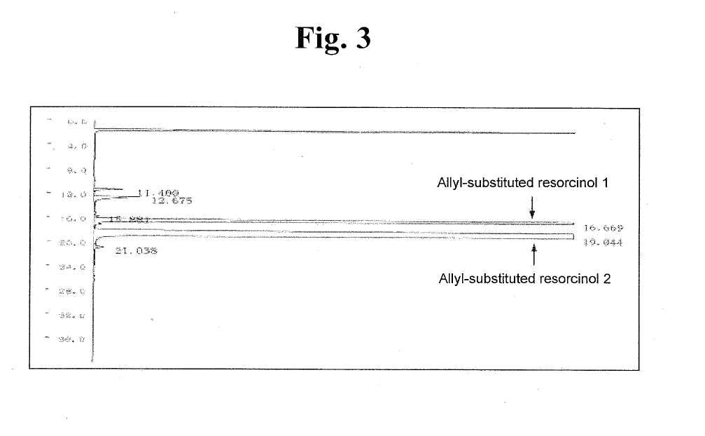

Examples of the GC analysis results are illustrated in FIGS. 2 and 3.

The sample 1 illustrated in FIG. 2 showed a peak (area ratio: 97%) assigned to the allyl-substituted resorcinol at a retention time of approximately 17 minutes. The sample 2 illustrated in FIG. 3 showed peaks assigned to the allyl-substituted resorcinols at retention times of approximately 17 minutes (area ratio: 21%) and 19 minutes (area ratio: 79%).

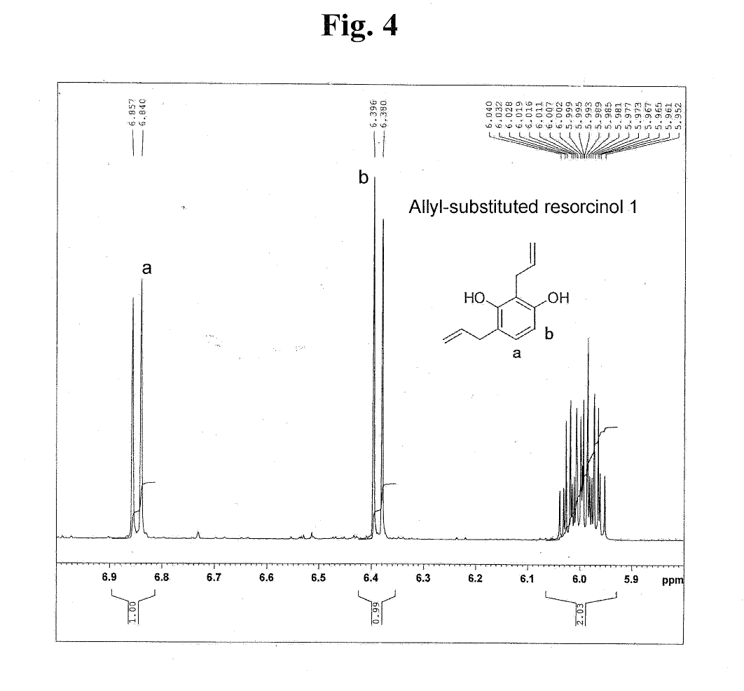

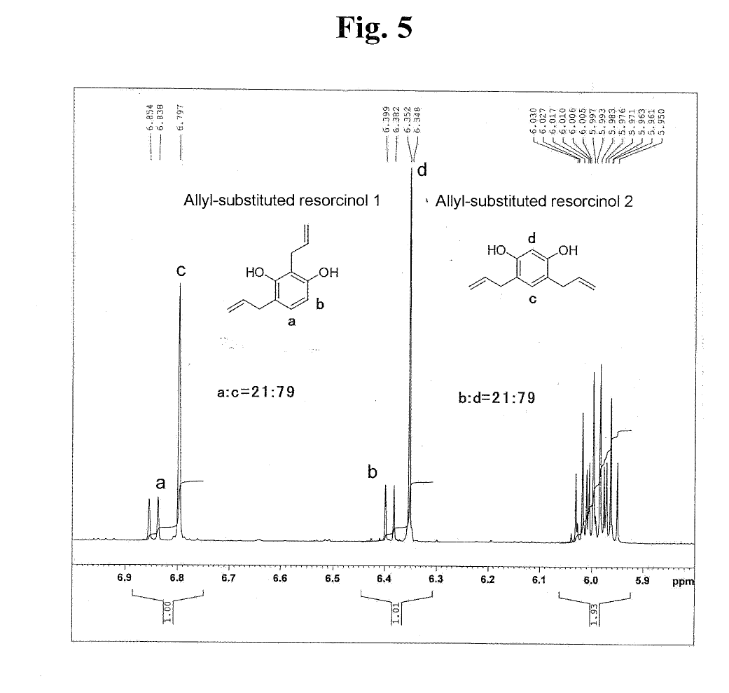

Further, the ¹H NMR analysis results of these samples are illustrated in FIGS. 4 and 5.

The sample 1 illustrated in FIG. 4 gave a single peak at each occurrence. The sample 2 illustrated in FIG. 5 showed two peaks at each occurrence, and the integral ratio of the respective peaks was 21:79, which is substantially identical with the GC analysis results.

[symbol]

Methods of Analysis for Phenolic Oligomers and Cured Products

[symbol]

### (1) Rotational Viscosity

E-type viscometer TVH manufactured by TOKI SANGYO CO., LTD. was used.

Approximately 1.2 ml of a specimen (the phenolic oligomer obtained in any of Examples 1 to 9) was placed into a cup attached to the E-type viscometer, and the cup was set in a thermostatic chamber-liquid feed device (F25-MP manufactured by Julabo) at 25° C. or 50° C.

The E-type viscometer was operated to start the measurement of rotational viscosity of the specimen. The value of rotational viscosity was read after the reading became stabilized.

### (2) OH Equivalent

(Summary: A specimen was acetylated with acetyl chloride, the excess acetyl chloride was hydrolyzed, and the hydroxyl equivalent was determined by alkali titration.)

A specimen (the phenolic oligomer obtained in any of Examples 1 to 9) 1 g was precisely weighed and combined with 10 ml of 1,4-dioxane to give a solution.

After the dissolution was confirmed, 10 ml of a 1.5 mol/L acetyl chloride solution in anhydrous toluene was added. The mixture was cooled to 0° C.

Pyridine 2 ml was added, and the reaction was carried out in a water bath at 60±1° C. for 1 hour.

After the reaction, the reaction liquid was cooled and combined with 25 ml of pure water. The mixture was stirred sufficiently to hydrolyze acetyl chloride.

Acetone 25 ml and phenolphthalein were added.

The specimen solution was titrated against a 1 mol/L aqueous potassium hydroxide solution until the specimen solution turned red purple.

The procedures were repeated using a blank (no specimen added).

The hydroxyl equivalent was obtained by the following calculations.

OH equivalent [g/eq.]=(1000×W)/(f×(B−A))

Here, W, f, B and A were:

W: specimen weight [g]

f: factor of the 1 mol/L aqueous potassium hydroxide solution=1.002

B: volume [ml] of the 1 mol/L aqueous potassium hydroxide solution required for the blank measurement

A: volume [ml] of the 1 mol/L aqueous potassium hydroxide solution required for the specimen measurement

### (3) Water Absorption Rate

A specimen (an epoxy resin composition having formulation described in Table 3 or 4) was cured in a mold at 150° C. for 5 hours and 180° C. for 8 hours to form a molded sample.

Size: (diameter 50±1)×(3±0.2) (diameter×thickness, mm)

The surface of the sample was sufficiently wiped, and the specimen weight was measured.

The sample was placed into a 100 ml sample bottle, and 80 ml of pure water was added.

The sample was allowed to absorb water for 24 hours in a hot air circulation dryer at 95° C.

The sample was removed from the dryer and cooled to 25° C. in a low-temperature thermostatic water bath.

After the sample was cooled, water on the surface was sufficiently removed, and the sample was weighed.

The water absorption rate was calculated according to the following equation:

Water absorption rate [%]=((B−A)/A)×100

A: weight [g] before water absorption

B: weight [g] after water absorption

### (4) Glass Transition Temperature (Tg)

A specimen (an epoxy resin composition having formulation described in Table 3 or 4) was cured in a mold at 150° C. for 5 hours and 180° C. for 8 hours, and was cut into the following size to give a sample.

Size: (50±1)×(40±1)×(100±1) (length×width×height, mm)

The specimen was set in tester TMA-60 (manufactured by SHIMADZU) and was tested in a N₂ atmosphere.

The measurement was continued until the temperature was raised to 350° C. at a heating rate of 3° C./min. The glass transition temperature (Tg) was obtained by determining the inflection point temperature.

The glass transition temperature is an indicator of heat resistance. The higher the glass transition point, the higher the heat resistance.

### (5) Gel Time

A specimen (an epoxy resin composition having formulation described in Table 3 or 4) was placed into a test tube, and the test tube was soaked in an oil bath at 150° C. The epoxy resin composition was stirred with a glass rod once per second. The time required for the composition to come to resist stirring strongly was obtained as the gel time.

### (6) Mechanical Properties (Elastic Modulus and Stress) of Cured Products

A specimen (an epoxy resin composition having formulation described in Table 3 or 4) was cured in a mold at 150° C. for 5 hours and 180° C. for 8 hours, and was cut into the following size to give a sample.

Size: (75±1)×(6±1)×(4±1) (length×width×thickness, mm)

Tester: autograph (model: AG-5000D manufactured by SHIMADZU)

A compression bending test was performed at room temperature with a head speed of 2.0 mm/min and a distance between two points of 50 mm.

### (7) GPC

Gel permeation chromatography (GPC) was performed under the following conditions to determine the degrees (n) of condensation polymerization of the phenolic oligomers, and the average degree of condensation polymerization of the phenolic oligomers.

Chromatograph: gel permeation chromatograph (HLC-8020) manufactured by TOSOH CORPORATION.

Columns: four TSKgel G2000 HXL columns, one G3000 HXL column and one G4000 HXL column manufactured by TOSOH CORPORATION were connected in series.

Eluent: tetrahydrofuran

Eluent flow rate: 1.0 mL/min

Column temperature: 40° C.

Detection method: visible detector (UV)

Calibration curve: prepared using polystyrene standards

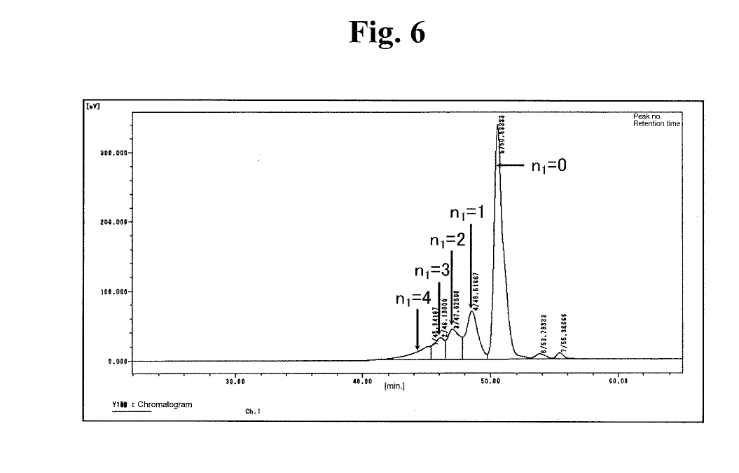

As an example of the GPC measurement results, the results in Example 1 are illustrated in FIG. 6. In the figure, the assignments of the peaks to the degrees of condensation polymerization are:

approximately 50.5 minute retention time assigned to n=0,

approximately 48.5 minute retention time assigned to n=1,

approximately 47.0 minute retention time assigned to n=2,

approximately 46.1 minute retention time assigned to n=3, and

approximately 45.3 minute retention time assigned to n=4.

By multiplying the respective peak areas by the corresponding degrees (n) of condensation polymerization, and dividing the total of the products by the total of the peak areas, the average degree of condensation polymerization was calculated to be 0.8.

By dividing the total of the areas of the peaks assigned to n=0 to 4 by the total peak area, the purity was calculated to be 96.2%.

Tables 1 and 2 describe the purities of the dihydric, allyl-substituted phenol compounds used as materials in Examples 1 to 9 and Comparative Examples 1 to 3, as well as the proportions of 4,6-diallyl isomer, the conditions for the synthesis of allyl-substituted phenol compounds, and properties of the resulting phenolic oligomers.

In Table 2, “Solid” or “Semisolid” indicates that the phenol compound was not liquid at 25° C. or 70° C. and the E-type viscosity was not measured.

Epoxy resin compositions were prepared by adding an epoxy resin and a curing accelerator to the phenolic oligomers as curing agents obtained in Examples 1 to 9 and Comparative Examples 1 to 3. The epoxy resin was EPIKOTE 828EL (bisphenol A liquid epoxy resin, epoxy equivalent 186 g/eq) manufactured by Japan Epoxy Resins Co., Ltd. The curing accelerator was 2E4MZ (2-ethyl-4-methylimidazole) manufactured by SHIKOKU CHEMICALS CORPORATION. The epoxy resin compositions were formulated such that the epoxy equivalent of the epoxy resin was equal to the hydroxyl equivalent of the phenolic oligomer. The formulations of the epoxy resin compositions are described in Tables 3 and 4.

The epoxy resin composition was heated to 150° C. and was melt mixed. After vacuum defoaming, the composition was poured into a mold heated to 150° C. The composition was cured at 150° C. for 5 hours and 180° C. for 8 hours to give an epoxy resin cured product. Properties and characteristics of the resulting epoxy resin cured products are also described in Tables 3 and 4.

In Tables 3 and 4, a₁ indicates a linear expansion coefficient at a temperature of not more than the glass transition point (Tg), and a₂ indicates a linear expansion coefficient at a temperature of not less than the glass transition point (Tg).

TABLE 1

| | | Example | Example | Example | Example | Example | Example | Example | Example | Example |
|---|---|---|---|---|---|---|---|---|---|---|
| | | 1 | 2 | 3 | 4 | 5 | 6 | 7 | 8 | 9 |
| Material | Proportion of 4,6- | 48 | 48 | 48 | 48 | — | 43 | 29 | 65 | 23 |
| | diallyl isomer | | | | | | | | | |
| | Purity (%) | 93 | 93 | 93 | 93 | 87 | 89 | 90 | 88 | 96 |
| | of dihydric, | | | | | | | | | |
| | allyl-substituted | | | | | | | | | |
| | phenol compound | | | | | | | | | |
| Synthetic | Allyl-substituted | Allyl- | Allyl- | Allyl- | Allyl- | Allyl- | Allyl- | Allyl- | Allyl- | Allyl- |
| conditions | phenol compound | substituted | substituted | substituted | substituted | substituted | substituted | substituted | substituted | substituted |
| | (mol) | resorcinol | resorcinol | resorcinol | resorcinol | catechol | resorcinol | resorcinol | resorcinol | resorcinol |
| | | (0.15) | (0.30) | (0.30) | (0.08) | (2.00) | (0.30) | (0.30) | (0.24) | (0.22) |
| | Formaldehyde | 42% | 42% | 42% | 42% | 42% | 42% | 42% | 42% | 42% |
| | (mol) | Formalin | Formalin | Formalin | Formalin | Formalin | Formalin | Formalin | Formalin | Formalin |
| | | (0.08) | (0.15) | (0.08) | (0.05) | (0.10) | (0.15) | (0.15) | (0.12) | (0.11) |
| | Acid catalyst | −(no acid | Oxalic | Oxalic | Hydrochloric | Oxalic | Oxalic | Oxalic | Oxalic | Oxalic |
| | | used) | acid | acid | acid | acid | acid | acid | acid | acid |
| Properties | State of resin | Liquid | Liquid | Liquid | Liquid | Solid | Liquid | Liquid | Liquid | Liquid |
| | at 25° C. | | | | | | | | | |
| | Rotational | 89 | 91 | 1.6 | 124 | — | 32 | 26 | 72 | 25 |
| | viscosity | | | | | | | | | |
| | (Pa · s/25° C.) | | | | | | | | | |
| | State of resin | Liquid | Liquid | Liquid | Liquid | Liquid | Liquid | Liquid | Liquid | Liquid |
| | at 70° C. | | | | | | | | | |
| | Rotational | 0.54 | 0.55 | 0.05 | 0.65 | 14.3 | 0.32 | 0.28 | 0.51 | 0.25 |
| | viscosity | | | | | | | | | |
| | (Pa · s/70° C.) | | | | | | | | | |
| | OH equivalent | 112 | 109 | 107 | 110 | 121 | 108 | 108 | 113 | 107 |
| | (g/eq.) | | | | | | | | | |
| | PS equivalent | 622 | 644 | 490 | 657 | 725 | 671 | 682 | 704 | 694 |
| | Mn | | | | | | | | | |
| | PS equivalent | 709 | 691 | 574 | 712 | 843 | 693 | 699 | 739 | 713 |
| | Mw | | | | | | | | | |

TABLE 2

| | | Comparative | Comparative | Comparative |
|---|---|---|---|---|
| | | example 1 | example 2 | example 3 |
| Material | Proportion of | — | — | — |
| | 4,6-diallyl | | | |
| | isomer | | | |
| | Purity (%) of | — | — | — |
| | dihydric, allyl- | | | |
| | substituted | | | |
| | phenol | | | |
| | compound | | | |
| Synthetic | Allyl-substituted | o- | — | — |
| conditions | phenol | Allylphenol | | |
| | compound (mol) | (5.00) | | |
| | Formaldehyde | 42% | | |
| | (mol) | Formalin | — | — |
| | | (1.00) | | |
| | Acid catalyst | Oxalic acid | — | — |
| Properties | State of resin at | Liquid | Semisolid | Solid |
| | 25° C. | | | |
| | Rotational | 1.7 | — | — |
| | viscosity | | | |
| | (Pa · s/25° C.) | | | |
| | State of resin at | Liquid | Liquid | Solid |
| | 70° C. | | | |
| | Rotational | 0.07 | 1.1 | — |
| | viscosity | | | |
| | (Pa · s/70° C.) | | | |
| | OH equivalent | 144 | 160 | 145 |
| | (g/eq.) | | | |
| | PS equivalent | 529 | 608 | 1018 |
| | Mn | | | |
| | PS equivalent | 564 | 789 | 2429 |
| | Mw | | | |

TABLE 3

| | | Example | Example | Example | Example | Example | Example | Example | Example | Example |
|---|---|---|---|---|---|---|---|---|---|---|
| | | 1 | 2 | 3 | 4 | 5 | 6 | 7 | 8 | 9 |
| Amounts | Epoxy resin* | 100 | 100 | 100 | 100 | 100 | 100.0 | 100.0 | 100.0 | 100.0 |
| | (parts) | | | | | | | | | |
| | Curing agent | 60.2 | 58.8 | 57.3 | 59.1 | 65.1 | 58.2 | 57.4 | 60.5 | 57.3 |
| | (parts) | | | | | | | | | |
| | Imidazole (% | 0.60 | 0.60 | 0.30 | 0.60 | 0.15 | 0.30 | 0.30 | 0.30 | 0.30 |
| | to epoxy resin) | | | | | | | | | |
| Properties | Gel time | 18 | 18 | 9 | 17 | 12 | 28 | 18 | 105 | 15 |
| | (min./150° C.) | | | | | | | | | |
| | Water | 1.7 | 1.8 | 2.1 | 1.8 | 2.1 | 1.46 | 1.45 | 1.49 | 1.48 |
| | absorption | | | | | | | | | |
| | rate (%) | | | | | | | | | |
| | Tg (° C.) | 133 | 130 | 98 | 134 | 139 | 126 | 127 | 125 | 126 |
| | α₁ (ppm) | 79 | 79 | 79 | 78 | 81 | 80 | 81 | 81 | 79 |
| | α₂ (ppm) | 175 | 188 | 193 | 175 | 194 | 187 | 183 | 198 | 187 |
| | Elastic | 2.2 | 2.3 | 2.5 | 2.3 | 2.8 | 2.3 | 2.3 | 2.4 | 2.3 |
| | modulus | | | | | | | | | |
| | (GPa) | | | | | | | | | |
| | Stress (MPa) | 106 | 109 | 109 | 107 | 112 | 107 | 105 | 111 | 105 |

TABLE 4

| | | Comparative | Comparative | Comparative |
|---|---|---|---|---|
| | | example 1 | example 2 | example 3 |
| Amounts | Epoxy resin* | 100 | 100 | 100 |
| | (parts) | | | |
| | Curing agent | 77.4 | 86.0 | 78.0 |
| | (parts) | | | |
| | Imidazole (% | 0.50 | 0.25 | 0.25 |
| | to epoxy resin) | | | |
| Properties | Gel time | 4 | 8 | Melting did |
| | (min./150° C.) | | | not occur, |
| | Water | 1.7 | 1.7 | and |
| | absorption | | | properties |
| | rate (%) | | | were not |
| | Tg (° C.) | 79 | 97 | measured. |
| | α₁ (ppm) | 78 | 100 | |
| | α₂ (ppm) | 198 | 180 | |
| | Elastic modulus | 2.8 | 2.7 | |
| | (GPa) | | | |
| | Stress (MPa) | 103 | 111 | |

From the results in Examples, it can be understood that the epoxy resin compositions produced in Examples are useful as sealing materials and underfill materials for sealing semiconductor elements.

1. A phenolic oligomer of the following general formula (1): 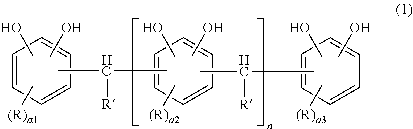
wherein n is an integer of 0 to 15,
Rs are allyl groups,
a1 and a3 are each independently 0, 1, 2, or 3,
each a2 is independently 0, 1, or 2,
each R′ is independently a hydrogen atom, an alkyl group having 1 to 10 carbon atoms, or an aryl group, and
wherein at least one of a1, a2, and a3 is 2.

2. A method for producing a phenolic oligomer, comprising a step of reacting a phenol compound component comprising at least one dihydric, allyl-substituted phenol compound of the following general formula (2): 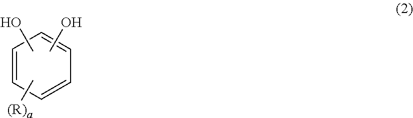
wherein R is an allyl group, and a is 1, 2 or 3, with at least one aldehyde compound of the following general formula (3):
R′CHO (3)
wherein R′ is a hydrogen atom, an alkyl group having 1 to 10 carbon atoms or an aryl group.

3. The method according to claim 2, wherein the phenol compound component further comprises at least one monohydric phenol compound of the following general formula (4): 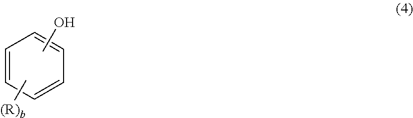
wherein R is an allyl group, and b is 0, 1, 2 or 3.

4. The method of claim 2, wherein the molar ratio of the phenol compound component to the aldehyde compound is 1.2:1 to 10:1.

5. The method of claim 2, wherein the phenol compound component comprises an allyl-substituted resorcinol.

6. The method of claim 2, wherein the phenol compound component comprises 2,4-diallylresorcinol and 4,6-diallylresorcinol as main components.

7. The method according to claim 6, wherein the proportion of 4,6-diallylresorcinol in the phenol compound component is from 15 mol % to 75 mol %.

8. The method of claim 2, wherein the reaction is carried out without catalysts or in the presence of an acid catalyst.

9. The method of claim 2, wherein a dihydric, allyl-substituted phenol compound is used as a phenol compound component which is obtained by allyl-etherifying a hydroxyl group of a dihydric phenol and introducing the allyl group onto the phenol nucleus by Claisen rearrangement.

10. A phenolic oligomer obtained by the method of claim 2.

11. The phenolic oligomer according to claim 1, having rotational viscosity of 0.01 to 150 Pa·s as measured at 25° C. with an E-type viscometer.

12. An epoxy resin curing agent comprising the phenolic oligomer according to claim 1.

13. An epoxy resin obtained by a reaction of the phenolic oligomer of claim 1, with an epihalohydrin.

14. An epoxy resin composition comprising a phenolic oligomer of the following general formula (1): 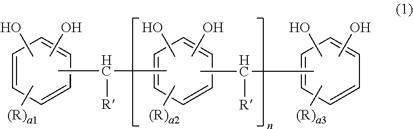
wherein n is an integer of 0 to 15, Rs are allyl groups, a1 and a3 are each independently 0, 1, 2, or 3, each a2 is independently 0, 1, or 2, each R′ is independently a hydrogen atom, an alkyl group having 1 to 10 carbon atoms, or an aryl group, and wherein at least one of a1, a2, and a3 is 2; and
an epoxy resin obtained by a reaction of a phenolic oligomer of the following general formula (1): 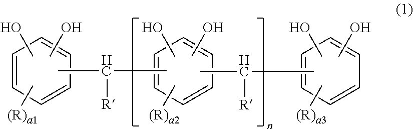
wherein n is an integer of 0 to 15, Rs are allyl groups, a1 and a3 are each independently 0, 1, 2, or 3, each a2 is independently 0, 1, or 2, each R′ is independently a hydrogen atom, an alkyl group having 1 to 10 carbon atoms, or an aryl group, u and wherein at least one of a1, a2, and a3 is 2 with an epihalohydrin.

15. An epoxy resin composition comprising a phenol resin, and the epoxy resin of claim 13.

16. An epoxy resin composition comprising the phenolic oligomer according to claim 1, and an epoxy resin.

17. An epoxy resin cured product obtained by curing the epoxy resin composition of claim 14.

18. A sealing material for semiconductor elements comprising the epoxy resin composition of claim 14.

19. An underfill material for semiconductor elements comprising the epoxy resin composition of claim 14.

20. A semiconductor device sealed with a sealing material or with an underfill material comprising the epoxy resins of claim 14.
